(19) United States
(12) Patent Application Publication
(10) Pub. No.: US 2025/0368791 A1
(43) Pub. Date: Dec. 4, 2025

(54) NON-WOVEN FABRIC PREPREG, METAL-FOIL-CLAD PLATE AND PRINTED CIRCUIT BOARD

(71) Applicant: SHENGYI TECHNOLOGY CO., LTD., Dongguan (CN)

(72) Inventors: Songgang CHAI, Dongguan (CN); Qianfa LIU, Dongguan (CN); Wei LIANG, Dongguan (CN); Liangpeng HAO, Dongguan (CN)

(21) Appl. No.: 18/877,947

(22) PCT Filed: Dec. 13, 2022
(86) PCT No.: PCT/CN2022/138718

§ 371 Date: Dec. 20, 2024

(30) Foreign Application Priority Data
Jul. 5, 2022 (CN) 202210790517.X

(51) Int. Cl. C08J 5/24; C08K 3/22; C08K 3/36; C08K 3/38; C08K 9/06; H05K 1/03

(52) U.S. Cl. CPC C08J 5/244; C08J 5/248; C08K 3/36; C08K 9/06; H05K 1/0366; H05K 1/0373; C08J 2327/18; C08K 2003/2241; C08K 2003/385; C08K 2201/005; H05K 2201/0209; H05K 2201/0293

(57) ABSTRACT

The present invention provides a non-woven fabric prepreg, a metal-foil-clad plate and a printed circuit board. The non-woven fabric prepreg comprises a fluorine-containing resin binder non-woven fabric and a fluorine-containing resin composition, wherein the fluorine-containing resin binder non-woven fabric comprises a binder and inorganic fibers, and the binder is a fluorine-containing resin emulsion; and the fluorine-containing resin composition comprises, in parts by weight, 30-100 parts of a fluorine-containing resin emulsion, and 0-70 parts of an inorganic filler. The non-woven fabric prepreg and a copper-clad plate containing the non-woven fabric prepreg of the present invention have good dielectric properties and a low thermal expansion coefficient, such that the copper-clad plate can meet the performance requirements of the high-frequency communication field on a copper-clad plate material.

### TECHNICAL FIELD

The present application belongs to the technical field of communication materials, and especially relates to a non-woven fabric prepreg, a metal-clad laminate, and a printed circuit board.

### BACKGROUND

Copper-clad laminate, as one of the key basic materials in the industry of electronic communication and information, is widely used in the field of mobile phones, computers, vending machines, communication base stations, satellites and wearable devices, pilotless automobiles, unmanned aerial vehicles, and intelligent robots. Polytetrafluoroethylene (PTFE), a representative fluorine-containing resin, is an ideal base material for the preparation of copper-clad laminates due to its excellent properties such as low dielectric loss, high thermal stability and high chemical stability. Since the 1950s, researchers have gradually improved the manufacturing process of PTFE-based copper-clad laminates through the continuous optimization of formulas and parameters.

The fluorine-containing resin has very flexible polymer chains, and it is usually necessary to introduce inorganic materials to improve the mechanical strength of fluorine-containing resin-based copper-clad laminates. For example, CN104175686A discloses a preparation method for a PTFE composite substrate for microwave circuits, and the method comprises: firstly, mixing a fluorine resin emulsion, an inorganic filler, and a thickener to prepare a stable and homogeneous dispersion, and then coating the dispersion on a release base material, baking and then separating the resin layer and the base material, laminating the separated resin layer with copper foils, and then performing high-temperature lamination and sintering to obtain a double-sided copper-clad PTFE composite substrate; wherein the inorganic filler is preferably silicon dioxide and/or titanium dioxide. CN101838431A discloses a fluororesin mixture and a copper-clad laminate made therefrom, in which the fluororesin mixture comprises a polytetrafluoroethylene perfluoroalkylvinyl ether emulsion, a polytetrafluoroethylene emulsion, an inorganic filler, and a diluent, and the inorganic filler is silica micro-powder, kaolin, or titanium dioxide powder.

The fluorine-containing resin has very flexible polymer chains, and it is usually necessary to introduce the reinforcing material of glass fiber cloth to improve the mechanical strength of the fluorine-containing resin copper-clad laminate. The weaving structure of the glass fiber cloth in warp and weft directions causes non-uniformity of the dielectric properties among different locations on the copper-clad laminate; in addition, the use of the glass fiber cloth limits the addition of large amounts of inorganic fillers to the fluorine-containing resin substrate. For example, U.S. Pat. No. 4,225,180A discloses mixing a microfiber and an inorganic filler into a PTFE emulsion successively, and then filtering and drying to obtain a fluorine-containing resin mixture, laminating the same into a board to obtain the fluorine-containing resin-based copper-clad laminate without glass fiber cloth reinforcing.

Therefore, it is urgent in this field to develop a copper-clad laminate that has excellent dielectric properties, thermal expansion coefficient, and mechanical strength.

### SUMMARY

In view of the shortcomings of the prior art, an object of the present application is to provide a non-woven fabric prepreg, a metal-clad laminate, and a printed circuit board. The prepreg comprises a fluorine-containing resin binder non-woven fabric and a fluorine-containing resin composition, and the copper-clad laminate prepared from the non-woven fabric prepreg has excellent dielectric properties, thermal expansion coefficient, and mechanical strength.

To achieve this object, the present application adopts the following technical solutions.

In one aspect, the present application provides a non-woven fabric prepreg; the non-woven fabric prepreg comprises a fluorine-containing resin binder non-woven fabric and a fluorine-containing resin composition, wherein the fluorine-containing resin binder non-woven fabric comprises a binder and an inorganic fiber, and the binder is a fluorine-containing resin emulsion; and the fluorine-containing resin composition comprises, by weight, 30-100 parts of a fluorine-containing resin emulsion, and 10-70 parts of an inorganic filler.

In the present application, by using the binder of fluorine-containing resin emulsion, the non-woven fabric has low dielectric loss, good uniformity, consistent thickness, isotropic fiber orientation, and high tensile strength, and a large amount of dielectric fillers can be added when the non-woven fabric is impregnated with the low-dielectric-loss resin to prepare high-frequency copper-clad laminates with low dielectric loss. The non-woven fabric prepared by the binder containing the fluorine-containing resin emulsion is matched with the fluorine resin emulsion and inorganic filler, so that the copper-clad laminate prepared by the prepreg has excellent dielectric properties, thermal expansion coefficient, and mechanical strength.

In the present application, the fluorine-containing resin composition comprises 30-100 parts by weight of the fluorine-containing resin emulsion, such as 30 parts, 32 parts, 34 parts, 36 parts, 38 parts, 40 parts, 42 parts, 44 parts, 46 parts, 48 parts, 50 parts, 52 parts, 54 parts, 56 parts, 58 parts, 60 parts, 62 parts, 64 parts, 68 parts, 70 parts, 72 parts, 74 parts, 80 parts, 86 parts, 88 parts, 90 parts, 94 parts, 96 parts, 98 parts, 100 parts, etc.

The fluorine-containing resin composition comprises 10-70 parts by weight of the inorganic filler, such as 10 parts, 16 parts, 18 parts, 20 parts, 24 parts, 26 parts, 30 parts, 32 parts, 34 parts, 36 parts, 38 parts, 40 parts, 42 parts, 44 parts, 46 parts, 48 parts, 50 parts, 52 parts, 54 parts, 56 parts, 58 parts, 60 parts, 62 parts, 64 parts, 66 parts, 68 parts, etc.

In the present application, the fluorine-containing resin emulsion in the binder and the fluorine-containing resin emulsion in the fluorine-containing resin composition are each independently selected from any one or a combination of at least two of a polytetrafluoroethylene emulsion, a fluorinated ethylene propylene emulsion, a polyvinylidene fluoride emulsion, a tetrafluoroethylene-perfluoroalkylvinyl ether copolymer emulsion, an ethylene-tetrafluoroethylene copolymer emulsion, a polytrifluorochloroethylene emulsion, or an ethylene-trifluorochloroethylene copolymer emulsion.

Preferably, in the fluorine-containing resin binder non-woven fabric, a weight percentage of the inorganic fiber is 60-95% (e.g., 60%, 62%, 65%, 68%, 70%, 73%, 75%, 78%, 80%, 83%, 85%, 88%, 90%, 93%, or 95%), and a weight percentage of the binder is 5-40% (e.g., 5%, 8%, 10%, 15%, 18%, 20%, 23%, 25%, 28%, 30%, 33%, 35%, 38%, or 40%). In the present application, if the weight percentage of the binder is too low, the binder cannot form a film unbrokenly, resulting in a low strength of the non-woven fabric, and if the weight percentage of the binder is too high, the non-woven fabric will have many internal pores and defects, resulting in a low strength of the non-woven fabric, further affecting the dielectric loss and bonding performance.

Preferably, a solid content of the fluorine-containing resin emulsion is 30-70%, such as 30%, 35%, 38%, 40%, 45%, 50%, 55%, 60%, 65%, or 70%.

Preferably, a particle size of a fluorine-containing resin in the fluorine-containing resin emulsion is 0.10-0.40 μm, such as 0.10 μm, 0.15 μm, 0.20 μm, 0.25 μm, 0.30 μm, 0.35 μm, or 0.40 μm.

In the present application, the particle size of the fluorine-containing resin emulsion is tested by laser diffraction method with an instrument of Malvern MS3000 laser particle analyzer. In the present application, the dielectric constant and dielectric loss are tested by the SPDR (split post dielectric resonator) method with a test condition of A-state and a frequency of 10 GHz.

Preferably, the inorganic fiber is selected from any one or a combination of at least two of an E-glass fiber, an NE-glass fiber, an L-glass fiber, a quartz fiber, an aluminum oxide fiber, a boron nitride fiber, a silicon carbide fiber, a zinc oxide fiber, a magnesium oxide fiber, a silicon nitride fiber, a boron carbide fiber, an aluminum nitride fiber, an aluminum oxide whisker, a boron nitride whisker, a silicon carbide whisker, a zinc oxide whisker, a magnesium oxide whisker, a silicon nitride whisker, a boron carbide whisker, or an aluminum nitride whisker.

Preferably, the inorganic fiber has an average diameter of less than 13 μm, such as 12 μm, 10 μm, 9 μm, 8 μm, 7 μm, 6 μm, 5 μm, 4 μm, 3 μm, 2 μm, 1 μm, or 0.5 μm, preferably less than 10 μm, and preferably 0.5-5 μm.

Preferably, the inorganic fiber has an average length of 1-100 mm, such as 2 mm, 5 mm, 8 mm, 10 mm, 30 mm, 50 mm, 80 mm or 100 mm, preferably 1-10 mm. The average diameter and the average length of the inorganic fiber in the present application are measured with a scanning electron microscope.

Preferably, the binder can be dissolved and diluted to a suitable viscosity by adding a solvent, so that the fiber and the binder in the prepared non-woven fabric can be uniformly dispersed; the solvent exemplarily comprises deionized water and the like. The solvent will be evaporated with the drying and sintering in the preparation of the non-woven fabric.

Preferably, the binder may also comprise a dispersant, a thickener, and an anti-foaming agent, etc.

Preferably, a preparation method of the fluorine-containing resin binder non-woven fabric comprises: mixing an inorganic fiber with a binder, impregnating, performing paper-making sheet forming, drying, and sintering to obtain the fluorine-containing resin binder non-woven fabric.

Preferably, the impregnation is performed for a period of 40-50 min, such as 40 min, 43 min, 45 min, 48 min, or 50 min.

Preferably, the drying is performed at a temperature of 120-150° C., such as 120° C., 125° C., 130° C., 135° C., 140° C., 145° C., or 150° C.; the drying is performed for a period of 1-30 min, such as 1 min, 3 min, 5 min, 8 min, 10 min, 13 min, 15 min, 18 min, or 20 min.

Preferably, the sintering is performed at a temperature of 250-350° C., such as 250° C., 270° C., 290° C., 300° C., 320° C., 340° C., or 350° C., and the sintering is performed for a period of 1-20 min, such as 1 min, 3 min, 5 min, 8 min, 10 min, 13 min, 15 min, 18 min, or 20 min.

Preferably, the fluorine-containing resin binder non-woven fabric has a unit weight (also known as mass per unit area) of 20-200 g/m², such as 20 g/m², 25 g/m², 30 g/m², 35 g/m², 40 g/m², 50 g/m², 60 g/m², 80 g/m², 100 g/m², 120 g/m², 150 g/m², 180 g/m², or 200 g/m², preferably 20-100 g/m². The fluorine-containing resin binder non-woven fabrics with different unit weights are obtained by adjusting the additive amounts of the inorganic fiber, the binder, and the solvent, as well as the machine speed.

Preferably, the inorganic filler comprises any one or a combination of at least two of spherical titanium dioxide, angular titanium dioxide, spherical silicon dioxide, hollow silicon dioxide, barium titanate, strontium titanate, a short-cut glass fiber, aluminum oxide, boron nitride, silicon nitride, an aluminum oxide whisker, a boron nitride whisker, or a hollow glass microsphere. The inorganic filler can be selected according to the demand; for example, the high DK filler is selected for the high DK board, and the thermal conductive filler is selected for thermal conductive boards.

In the present application, the prepregs prepared from different fillers combined with the fluorine-containing resin emulsion can meet different needs for dielectric performance and thermal conductivity performance, for example:

The fluorine-containing resin composition comprises, by weight of solid, 30-50 parts of the fluorine-containing resin, 25-35 parts of titanium dioxide, and 10-20 parts of silicon dioxide, which can be used to prepare a circuit substrate with a Dk of 6±0.5. The fluorine-containing resin by weight of solid herein refers to the fluorine-containing resin content in the fluorine-containing resin emulsion with the solvent removed, and can be calculated by the weight of the fluorine-containing resin emulsion times the solid content of the fluorine-containing resin emulsion.

The fluorine-containing resin composition comprises, by weight of solid, 30-40 parts of the fluorine-containing resin, 55-70 parts of titanium dioxide, and 5-20 parts of silicon dioxide, which can be used to prepare a circuit substrate with a Dk of 10±0.5.

The fluorine-containing resin composition comprises, by weight of solid, 30-60 parts of the fluorine-containing resin, 20-40 parts of boron nitride, 4-10 parts of titanium dioxide, and 10-20 part of silicon dioxide, which can be used to prepare a circuit substrate with a Dk of 3.5±0.5 and a thermal conductivity of more than 1.44 W/mk.

The fluorine-containing resin composition comprises, by weight of solid, 40-60 parts of the fluorine-containing resin, 0-10 parts of titanium dioxide, and 40-60 parts of silicon dioxide, which can be used to prepare a circuit substrate with a Dk of 3±0.5.

As a preferred technical solution of the present application, the inorganic filler has surface modification. By surface modification with reagents, the prepared copper-clad laminate has better dielectric properties and lower thermal expansion coefficient.

Preferably, a surface modifier used for the surface modification is a silane coupling agent.

Preferably, the silane coupling agent comprises any one or a combination of at least two of a fluorine-containing silane coupling agent, an amino silane coupling agent, an epoxy silane coupling agent, a vinyl silane coupling agent, or an acrylic silane coupling agent.

Preferably, based on the mass of an inorganic filler to be surface-treated being 100%, a usage amount of the surface modifier is 0.05-0.5%, which may be, for example, 0.05%, 0.1%, 0.15%, 0.2%, 0.25%, 0.3%, 0.35%, 0.4%, 0.45%, or 0.5%, etc.

Exemplarily, the fluorine-containing resin composition is prepared by the following method, and the method comprises: mixing a fluorine-containing resin emulsion and an inorganic filler and then dispersing evenly to obtain the fluorine-containing resin composition.

In the preparation process, a thickener, a dispersant, or a solvent can also be added to the fluorine-containing resin composition, and the additive amount is selected by those skilled in the art according to the experience and process requirements to obtain the viscosity suitable for the impregnation, coating, and use of the fluorine-containing resin composition. In the subsequent drying and sintering, the thickener and other additives will be partially or completely evaporated.

Preferably, the fluorine-containing resin binder non-woven fabric is impregnated with the fluorine-containing resin composition, dried and/or sintered to prepare the non-woven fabric prepreg.

Preferably, the drying is performed at a temperature of 100-260° C., which may be, for example, 110° C., 130° C., 150° C., 170° C., 190° C., 200° C., 210° C., 230° C., or 250° C., etc.

Preferably, the drying is performed for a period of 10-120 min, which may be, for example, 20 min, 30 min, 40 min, 50 min, 60 min, 70 min, 80 min, 90 min, 100 min or 110 min, etc.

Preferably, the sintering is performed at a temperature of 200-400° C., which may be, for example, 210° C., 230° C., 250° C., 270° C., 290° C., 300° C., 310° C., 330° C., 350° C., 370° C., or 390° C., etc.

Preferably, the sintering is performed for a period of 0.1-12 h, which may be, for example, 0.2 h, 0.25 h, 0.5 h, 0.75 h, 1 h, 1.5 h, 2 h, 2.5 h, 3 h, 4 h, 5 h, 6 h, 7 h, 8 h, 9 h, 10 h, or 11 h, etc.

Preferably, the sintering is performed in an inert atmosphere.

Preferably, the inert atmosphere comprises a nitrogen atmosphere and/or an argon atmosphere.

In another aspect, the present application provides a metal-clad laminate, and the metal-clad laminate comprises a metal foil and the non-woven fabric prepreg as described above.

Preferably, the metal foil is a copper foil, in which case the metal-clad laminate is a copper-clad laminate.

In another aspect, the present application provides a printed circuit board, and the printed circuit board comprises at least one of the non-woven fabric prepreg or the metal-clad laminate as described above.

Preferably, the printed circuit board is a high-frequency printed circuit board. In the present application, “high-frequency” is defined as a frequency of more than or equal to 1 GHz.

Compared to the prior art, the present application has the following beneficial effects.

For the non-woven fabric prepreg provided by the present application, by compounding a fluorine-containing resin composition with a low-dielectric-loss fluorine-containing resin binder non-woven fabric, the non-woven fabric prepreg and the copper-clad laminate containing the same have excellent dielectric properties, where the dielectric constant reaches 2.2-11 at 10 GHz, the dielectric loss is less than 0.003, and there is also a low thermal expansion coefficient, so that the copper-clad laminate can satisfy the performance requirements of copper-clad laminate materials in the high-frequency communication field.

### DETAILED DESCRIPTION

The technical solutions of the present application are further described below via specific embodiments. Those skilled in the art should understand that the examples are merely an aid to understanding the present application and should not be regarded as a specific limitation of the present application.

The experimental materials and devices used in the examples and comparative examples of the present application are as follows.

(1) Fluorine-containing resin composition A-1: 64 parts by weight of polytetrafluoroethylene emulsion (PTFE emulsion with a particle size of 0.25 μm and a solid content of 55%, manufactured by Daikin, Japan, product name: D210C), 10 parts by weight of FEP resin emulsion (with a solid content of 50 wt %, manufactured by Daikin, Japan, product name: ND-110), 3 parts of titanium dioxide (with an average particle size of 10 μm, purchased from Wuxi Noble, surface-treated with silane A171), and 60 parts of silicon dioxide (with an average particle size of 10 μm, purchased from Jiangsu Novoray) are stirred and mixed for 2 h to obtain the fluorine-containing resin composition A-1 resin.

Fluorine-containing resin composition A-2: 58.5 parts by weight of polytetrafluoroethylene emulsion (PTFE emulsion with a particle size of 0.25 μm and a solid content of 55%, manufactured by Daikin, Japan, product name: D210C), 32.5 parts of titanium dioxide (with an average particle size of 10 μm, purchased from Wuxi Noble), and 17 parts of silicon dioxide (with an average particle size of 10 μm, purchased from Jiangsu Novoray) are stirred and mixed for 2 h to obtain the fluorine-containing resin composition A-2 resin.

Fluorine-containing resin composition A-3: 55 parts by weight of polytetrafluoroethylene emulsion (PTFE emulsion with a particle size of 0.25 μm and a solid content of 55%, manufactured by Daikin, Japan, product name: D210C), 65 parts of titanium dioxide (with an average particle size of 10 μm, purchased from Wuxi Noble), and 18.5 parts of silicon dioxide (with an average particle size of 10 μm, purchased from Jiangsu Novoray, treated with silane KBM-503) are stirred and mixed for 2 h to obtain the fluorine-containing resin composition A-3 resin.

Fluorine-containing resin composition A-4: 60 parts by weight of polytetrafluoroethylene emulsion (PTFE emulsion with a particle size of 0.25 μm and a solid content of 55%, manufactured by Daikin, Japan, product name: D210C), 24 parts of boron nitride (with an average particle size of 10 μm, purchased from Anhui Estone), 6 parts of titanium dioxide (with an average particle size of 10 μm, purchased from Wuxi Noble), and 18 parts of silicon dioxide (with an average particle size of 10 μm, purchased from Jiangsu Novoray, treated with silane KBM-12) are stirred and mixed for 2 h to obtain the fluorine-containing resin composition A-4 resin.

(2) The specific preparation method for low-dielectric-loss non-woven fabric comprises the following steps.

The glass fiber and fluorine-containing emulsion are impregnated for 45 min, and subjected to paper-making sheet forming, and then dried in an oven at 150° C., then sintered in a high-temperature oven at 320° C. for 10 min, taken out and cooled down to obtain low-dielectric-loss non-woven fabrics with different unit weight. The usage amounts of the glass fiber, fluorine-containing emulsion, and binder, and the selection of the corresponding non-woven fabric are as follows:
low-dielectric-loss non-woven fabric B-1: E-glass fiber with an average diameter of 8 μm (China Jushi Co., Ltd.), FEP resin binder (with a solid content of 50 wt %, manufactured by Daikin, Japan, product name: ND-110), the binder with a content of 10%, and the non-woven fabric with a unit weight of 75 g/m²;
low-dielectric-loss non-woven fabric B-2: NE-glass fiber with an average diameter of 5 μm (China Jushi Co., Ltd.), PFA resin binder (with a solid content of 55 wt %, manufactured by Daikin, Japan, product name: AD-2CR), the binder with a content of 20%, and the non-woven fabric with a unit weight of 75 g/m²;
low-dielectric-loss non-woven fabric B-3: quartz glass fiber with average diameters of 0.5 μm and 5 μm (China Shenjiu), PTFE resin binder (with a solid content of 55 wt %, manufactured by Daikin, Japan, product name: D210C), the binder with a content of 20%, and the non-woven fabric with a unit weight of 25 g/m².

(3) Other reinforcing materials

Common non-woven fabric B-4: E-glass fiber with an average diameter of 12 μm, epoxy resin binder, Shaanxi Huatek, and the non-woven fabric with a unit weight of 75 g/m²;
non-woven fabric B-5: difference from the low-dielectric-loss non-woven fabric B-1, the binder content is 50%;
non-woven fabric B-6: prepared from an acrylate binder and an E-glass fiber with an average diameter of 13 μm, Shaanxi Huatek, and the non-woven fabric with a unit weight of 75 g/m²; E-glass fiber cloth: E-glass fiber, model: 106, Hubbell, Japan.

### Example 1

(1) The non-woven fabric B-1 was impregnated with the fluorine-containing resin composition A-1, dried in an oven at 100° C. for 1 h, and sintered in an oven at 360° C. for 0.5 h to obtain a fluorine-containing resin non-woven fabric prepreg with a thickness of 380 μm; and
(2) two fluorine-containing resin non-woven fabric prepregs were stacked with a size of 250 mm×250 mm, and copper foils with a thickness of 1 OZ were covered on the top and bottom sides of the stacked prepreg layer and laminated with an applied pressure of about 400 PSI, a maximum temperature of 380° C., and a retention period of 90 min, and the copper-clad laminate was obtained by lamination.

### Example 2

(1) The non-woven fabric B-2 was impregnated with the fluorine-containing resin composition A-1, dried in an oven at 100° C. for 1 h, and sintered in an oven at 360° C. for 0.5 h to obtain a fluorine-containing resin non-woven fabric prepreg with a thickness of 380 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Example 3

(1) The non-woven fabric B-3 was impregnated with the fluorine-containing resin composition A-2, dried in an oven at 100° C. for 1 h, and sintered in an oven at 360° C. for 0.5 h to obtain a fluorine-containing resin non-woven fabric prepreg with a thickness of 127 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Example 4

(1) The non-woven fabric B-3 was impregnated with the fluorine-containing resin composition A-3, dried in an oven at 100° C. for 1 h, and sintered in an oven at 360° C. for 0.5 h to obtain a fluorine-containing resin non-woven fabric prepreg with a thickness of 127 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Example 5

(1) The non-woven fabric B-3 was impregnated with the fluorine-containing resin composition A-4, dried in an oven at 100° C. for 1 h, and sintered in an oven at 360° C. for 0.5 h to obtain a fluorine-containing resin non-woven fabric prepreg with a thickness of 127 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Comparative Example 1

(1) The non-woven fabric B-4 was impregnated with the fluorine-containing resin composition A-1, dried in an oven at 100° C. for 1 h, and sintered in an oven at 360° C. for 0.5 h to obtain a fluorine-containing resin non-woven fabric prepreg with a thickness of 380 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Comparative Example 2

(1) The non-woven fabric B-5 was impregnated with the fluorine-containing resin composition A-1, dried in an oven at 100° C. for 1 h, and sintered in an oven at 360° C. for 0.5 h to obtain a fluorine-containing resin non-woven fabric prepreg with a thickness of 380 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Comparative Example 3

This comparative example differs from Example 1 only in that the non-woven fabric B-6 was used to replace the non-woven fabric B-1.

### Comparative Example 4

(1) The type-106 E-glass fiber cloth was impregnated with a fluorine-containing resin composition A-1, dried in an oven at 100° C. for 1 h, and sintered in an oven at 360° C. for 0.5 h to obtain a fluorine-containing resin non-woven fabric prepreg with a thickness of 100 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Comparative Example 5

(1) The non-woven fabric B-4 was impregnated with the fluorine-containing resin composition A-2, dried in an oven at 100° C. for 1 h, and sintered in an oven at 360° C. for 0.5 h to obtain a fluorine-containing resin non-woven fabric prepreg with a thickness of 127 μm; and
(2) two fluorine-containing resin non-woven fabric prepregs were stacked with a size of 250 mm×250 mm, and copper foils with a thickness of 1 OZ were covered on the top and bottom sides of the stacked resin layer and laminated with an applied pressure of about 400 PSI, a maximum temperature of 380° C., and a retention period of 90 min, and the copper-clad laminate was obtained by lamination.

### Performance Test

For the copper-clad laminates prepared in the above Examples and Comparative Examples, the following performance tests were performed:
(1) Dk and Df test: the SPDR (split post dielectric resonator) method was used for the test; the test condition was A-state and the frequency was 10 GHz; and
(2) Thermal expansion coefficient (X/Y): IPC-TM-650 2.4.24 was used to test an expansion variation coefficient of the material in the X/Y direction within a temperature range of −55° C. to 288° C.

The test results are shown in Table 1:

TABLE 1

| | | | Thermal expansion |
|---|---|---|---|
| | Dk (10 GHz) | Df (10 GHz) | coefficient (X/Y) |
| Example 1 | 3.10 | 0.0018 | 20/23 |
| Example 2 | 3.06 | 0.0013 | 18/20 |
| Example 3 | 6.41 | 0.0018 | 20/25 |
| Example 4 | 10.35 | 0.0025 | 16/20 |
| Example 5 | 3.50 | 0.0015 | 18/25 |
| Comparative | 3.15 | 0.0032 | 41/54 |
| Example 1 | | | |
| Comparative | 3.06 | 0.0038 | 40/51 |
| Example 2 | | | |
| Comparative | 3.20 | 0.0033 | 30/43 |
| Example 3 | | | |
| Comparative | 3.32 | 0.0040 | 40/77 |
| Example 4 | | | |
| Comparative | 6.48 | 0.0046 | 25/51 |
| Example 5 | | | |

As can be seen from the above table, in the non-woven fabric prepreg provided by the present application, the fluorine-containing resin binder non-woven fabric is impregnated with the fluorine-containing resin composition, so that the copper-clad laminate containing the non-woven fabric prepreg has excellent dielectric properties and low thermal expansion coefficient, which can meet the performance requirements of the copper-clad laminate material in the field of high-frequency communication.

As can be seen from Examples 1-5, the copper-clad laminates containing the non-woven fabric prepreg have a dielectric constant range of 3.06-10.35, a dielectric loss of <0.003, and a thermal expansion coefficient of <50 ppm; the dielectric loss and thermal expansion coefficient are all significantly better than those of the copper-clad laminates prepared from common non-woven fabrics and glass fiber woven fabrics. As can be seen from Comparative Examples 1, 3, and 5, when the common non-woven fabric is used as the impregnating material, the dielectric loss of the board is increased and the thermal expansion coefficient is large. In Comparative Example 4, when the common E-glass fiber cloth is used as the impregnating material, the dielectric loss of the board is higher; at the same time, due to the weaving structure of the glass fiber cloth, the thermal expansion coefficient is highly different in the X/Y direction.

In Comparative Example 2, the amount of fluorine-containing resin binder in the non-woven fabric is too large, resulting in an increase of pores in the copper-clad laminate; and compared to that in Example 1, the dielectric constant of the board is slightly reduced, but the dielectric loss is obviously increased, and the thermal expansion coefficient is increased.

In summary, the fluorine-containing resin binder non-woven fabric prepreg of the present application endows the copper-clad laminate containing the non-woven fabric prepreg with excellent dielectric properties, low thermal expansion coefficient, and other properties, which can be applied in the field of high-frequency communication.

The applicant declares that the non-woven fabric prepreg, the metal-clad laminate, and the printed circuit board of the present application are illustrated by the above examples in the present application, but the present application is not limited to the above examples, that is, the present application does not necessarily rely on the above examples to be implemented. Those skilled in the art should understand that any improvement of the present application, the equivalent substitution of each raw material of the product, the addition of auxiliary ingredients, and the selection of specific methods in the present application shall fall within the protection scope and disclosure scope of the present application.

1. A non-woven fabric prepreg, which comprises a fluorine-containing resin binder non-woven fabric and a fluorine-containing resin composition, the fluorine-containing resin binder non-woven fabric comprises a binder and an inorganic fiber, and the binder is a fluorine-containing resin emulsion; and the fluorine-containing resin composition comprises, by weight, 30-100 parts of a fluorine-containing resin emulsion and 10-70 parts of an inorganic filler.

2. The non-woven fabric prepreg according to claim 1, wherein the fluorine-containing resin emulsion is selected from any one or a combination of at least two of a polytetrafluoroethylene emulsion, a fluorinated ethylene propylene emulsion, a polyvinylidene fluoride emulsion, a tetrafluoroethylene-perfluoroalkylvinyl ether copolymer emulsion, an ethylene-tetrafluoroethylene copolymer emulsion, a polytrifluorochloroethylene emulsion, or an ethylene-trifluorochloroethylene copolymer emulsion.

3. The non-woven fabric prepreg according to claim 1, wherein the inorganic fiber is selected from any one or a combination of at least two of an E-glass fiber, an NE-glass fiber, an L-glass fiber, a quartz fiber, an aluminum oxide fiber, a boron nitride fiber, a silicon carbide fiber, a zinc oxide fiber, a magnesium oxide fiber, a silicon nitride fiber, a boron carbide fiber, an aluminum nitride fiber, an aluminum oxide whisker, a boron nitride whisker, a silicon carbide whisker, a zinc oxide whisker, a magnesium oxide whisker, a silicon nitride whisker, a boron carbide whisker, or an aluminum nitride whisker.

4. The non-woven fabric prepreg according to claim 1, wherein the inorganic filler comprises any one or a combination of at least two of spherical titanium dioxide, angular titanium dioxide, spherical silicon dioxide, hollow silicon dioxide, barium titanate, strontium titanate, a short-cut glass fiber, aluminum oxide, boron nitride, silicon nitride, an aluminum oxide whisker, a boron nitride whisker, or a hollow glass microsphere.

5. The non-woven fabric prepreg according to claim 1, wherein the inorganic filler has surface modification;

6. The non-woven fabric prepreg according to claim 1, wherein the fluorine-containing resin composition comprises, by weight of solid, 30-50 parts of a fluorine-containing resin, 25-35 parts of titanium dioxide, and 10-20 parts of silicon dioxide.

7. The non-woven fabric prepreg according to claim 1, wherein the fluorine-containing resin composition comprises, by weight of solid, 30-60 parts of a fluorine-containing resin, 20-40 parts of boron nitride, 4-10 parts of titanium dioxide, and 10-20 parts of silicon dioxide.

8. The non-woven fabric prepreg according to claim 1, wherein the fluorine-containing resin binder non-woven fabric is impregnated with the fluorine-containing resin composition, dried and sintered to prepare the non-woven fabric prepreg.

9. A metal-clad laminate, which comprises a metal foil and the non-woven fabric prepreg according to claim 1.

10. A printed circuit board, which comprises at least one of the non-woven fabric prepreg according to claim 1.

11. The non-woven fabric prepreg according to claim 2, wherein in the fluorine-containing resin binder non-woven fabric, a weight percentage of the inorganic fiber is 60-95%, and a weight percentage of the binder is 5-40%.

12. The non-woven fabric prepreg according to claim 2, wherein a solid content of the fluorine-containing resin emulsion is 30-70%.

13. The non-woven fabric prepreg according to claim 2, wherein a particle size of a fluorine-containing resin in the fluorine-containing resin emulsion is 0.10-0.40 μm.

14. The non-woven fabric prepreg according to claim 3, wherein the inorganic fiber has an average diameter of less than 13 μm, preferably less than 10 μm, and preferably 0.5-5 μm.

15. The non-woven fabric prepreg according to claim 3, wherein the inorganic fiber has an average length of 1-100 mm, preferably 1-10 mm.

16. The non-woven fabric prepreg according to claim 1, wherein the fluorine-containing resin composition comprises, by weight of solid, 30-40 parts of a fluorine-containing resin, 55-70 parts of titanium dioxide, and 5-20 parts of silicon dioxide.

17. The non-woven fabric prepreg according to claim 1, wherein the fluorine-containing resin composition comprises, by weight of solid, 40-60 parts of the fluorine-containing resin, 0-10 parts of titanium dioxide, and 40-60 parts of silicon dioxide.

18. The non-woven fabric prepreg according to claim 1, wherein the binder further comprises an anti-foaming agent with a weight percentage of 0.01-1%.

19. The non-woven fabric prepreg according to claim 1, wherein the fluorine-containing resin binder non-woven fabric has surface treatment, and a treating agent for the surface treatment is selected from one or a mixture of at least two of a fluorine-containing silane coupling agent, an amino silane coupling agent, an epoxy silane coupling agent, a vinyl silane coupling agent, an alkyl silane coupling agent, a borate coupling agent, a zirconate coupling agent, or a phosphate coupling agent.

20. The non-woven fabric prepreg according to claim 1, wherein the fluorine-containing resin binder non-woven fabric has a unit weight of 20-200 g/m², preferably 20-100 g/m².
